(19) United States
(12) Patent Application Publication
(10) Pub. No.: US 2018/0172760 A1
(43) Pub. Date: Jun. 21, 2018

(54) CONTACT DEVICE AND A METHOD OF TESTING A SINGULATED ELECTRONIC COMPONENT USING A CONTACT DEVICE

(71) Applicant: MULTITEST ELEKTRONISCHE SYSTEME GMBH, Rosenheim (DE)

(72) Inventors: Volker Leikermoser, Aschau im Chiemgau (DE); Manuel Petermann, Rosenheim (DE); Andreas Ludwig, Brannenburg (DE)

(21) Appl. No.: 15/845,853

(22) Filed: Dec. 18, 2017

(30) Foreign Application Priority Data
Dec. 20, 2016 (EP) 16 205 572.7

(51) Int. Cl. G01R 31/28; G01R 31/04

(52) U.S. Cl. CPC G01R 31/2863; G01R 31/045; G01R 31/2867; G01R 31/2893

(57) ABSTRACT

A contact device (200, 200′) and a method for testing a singulated electronic component (101). The contact device (200, 200′) comprises a plunger unit (202) comprising a chamber lid (220) and a nest (230) which is adapted to carry the singulated electronic component (101), and a socket unit (201) comprising a socket (132) and a chamber (210) having an open front side and surrounding the socket (132). The chamber (210) is adapted in that closing of the chamber (210) at its open front side (219) by the chamber lid (220) comprises automatically contacting the singulated electronic component (101) to the socket (132).

### CROSS-REFERENCE TO RELATED APPLICATION

This application claims priority to European Patent Application No. 16 205 572.7, filed on Dec. 20, 2016, the entire content of which is incorporated herein in by reference.

### FIELD OF INVENTION

The invention relates to a contact device for testing a singulated electronic component. Particularly, the invention relates to a method of using a contact device for testing a singulated electronic component.

### TECHNOLOGICAL BACKGROUND

After the front-end process of producing electronic components a part of these electronic components is inoperable. Therefore, the electronic components are tested in order to proof the operability and to sort the tested electronic components depending on the test results. To achieve this, each of the electronic components are fed to a plunger which carries one of the electronic components and which moves the electronic component to bring the electronic component in contact with a socket. The socket is electrically connected to a tester which performs the test routine on the electronic component. After the test, the tested electronic component is removed from the socket and sorted depending on the test result. There are electronic components which require certain pressure conditions and there are electronic components which are tested for high voltage applications.

### SUMMARY OF THE INVENTION

There may be a need to provide a device for and method of testing singulated electronic components under different pressure conditions. Further, there may be a need to provide a device for and method of testing electronic components by which device and by which method a high voltage test may be executed. In order to meet the need defined above a contact device for testing a singulated electronic component and a method of testing a singulated electronic component are provided according to independent claims.

According to an exemplary embodiment of the invention a contact device for testing a singulated electronic component comprises a plunger unit comprising a chamber lid and a nest which is adapted to carry the singulated electronic component, and a socket unit comprising a socket and a chamber having an open front side and surrounding the socket. The chamber may be adapted in that closing of the chamber at its open front side by the chamber lid comprises automatically contacting the singulated electronic component to the socket.

According to an exemplary embodiment of the invention a method of testing a singulated electronic component using a contact device is described. The described method comprises providing a plunger unit comprising a chamber lid and a nest which is adapted to carry the singulated electronic component, and providing a socket unit comprising a socket and a chamber having an open front side and surrounding the socket. Closing of the chamber at its open front side by the chamber lid may comprise automatically contacting the singulated electronic component to the socket.

The expression “contact device” may denote an apparatus or mechanism which establishes the junction of two electrical conductors through which current passes. Here, the contact device may enable contacting the singulated electronic component to a socket.

The expression “singulated electronic component” may denote a so called DUT (“device under test”), which means a semiconductor device which may have certain functions. In particular, an electronic component may be singulated if the electronic component is individualized and not in bulk or coupled with other electronic components of the same type.

The expression “plunger unit” may denote a device which comprises a mechanism for holding a singulated electronic component and to move the singulated electronic component towards a socket. The term “nest” may denote a movable receptacle prepared to carry a singulated electronic component. In particular, the nest may comprise lead backers, a rear element, a web and a base. The electronic component may be clamped between the web and the rear element. The lead backers may support terminals of the electronic component. The plunger unit may in general comprise a plunger rod and a movable nest coupled to the plunger rod.

The term “lid” may denote a movable cover for the opening of a hollow container or a chamber.

The expression “socket unit” may in general denote an apparatus which at least comprises a socket being adapted to contact with a singulated electronic component and to establish an electric junction of the singulated electronic component with a tester.

The term “socket” may denote in particular a contact socket, comprising DUT sided contacts for repeatedly contacting to DUTs and tester sided contacts to make an electric junction with a tester.

The term “chamber” may here denote an artificial enclosed space or cavity.

The expression “open front side” may denote that the chamber is not closed at a sector of the chamber body.

The expression “closing of the chamber” may denote that the chamber may be brought from forming an accessible cavity to an enclosed cavity or space.

The expression “automatically contacting the singulated electronic component to the socket” may denote that by closing the chamber with the chamber lid an operation is made which allows for appropriately contacting the singulated electronic component. In particular, closing of the chamber with the chamber lid may require a moving distance for the chamber lid which in turn causes a contacting process by which the singulated electronic component is contacted. The electronic component may be coupled to the movement of the chamber lid since the nest carries the singulated electronic component.

An idea of the invention may be that a closing procedure for a chamber with a movable chamber lid may be equivalent to a contacting procedure of a singulated electronic component with a socket since closing of the chamber with the chamber lid may require a distinct movement of the chamber lid which moving distance may be sufficient enough with a required contacting amplitude for contacting the singulated electronic component with the socket. That means, that closing of the chamber automatically may be equivalent to contacting the singulated electronic component to the socket if the singulated electronic component may be carried by the nest.

According to an exemplary embodiment of the contact device, the plunger unit further comprises at least one plunger rod, which may exert a closing force that moves the chamber lid in a direction to the open front side of the chamber and which moving force exceeds a contact force for contacting the singulated electronic component to the socket.

The expression “plunger rod” may denote a moving device formed as a slender bar as of metal to which the nest may be coupled. So, the singulated electronic component may be moved in a straight way forward and backward, and the electronic component may be exchanged after a backward movement.

The expression “exerts a closing force” may denote that by the plunger rod a force is exerted which moves the chamber lid towards the chamber and closes the chamber so that the chamber is getting airtight.

The expression “contact force for contacting to the singulated electronic component” may denote a force necessary of making sufficient contact of the terminals of the singulated electronic component with the DUT sided contacts of the socket. In particular, the closing force may go beyond the contact force so that there may be a force left which actually may make an airtight junction of the chamber lid with the chamber on its open front side.

According to an exemplary embodiment of the contact device, a suspension piece may be suspended with an elastic suspension on the chamber lid so that a force exerted by the elastic suspension on the suspension piece may be sufficient to contact the singulated electronic component to the socket.

The expression “suspended with an elastic suspension” may denote that something is flexibly hanged by a device to a base. The expression “suspension piece” may be a common denotation for a so called “lead backer” and for a “rear element”, as well. In particular, the rear element may be flexibly hanged by the suspension to the chamber lid. The expression “rear element” may denote a part of the nest and may be fixed to the base or may be a part of the base which may be suspended by an elastic suspension. The rear element may be adapted to support the back side of the electronic component. The electronic component may be clamped by the rear element and the web during the backward and forward movement.

Additionally, or alternatively, the lead backer may be suspended with an elastic suspension on the chamber lid so that a force exerted by the elastic suspension on the lead backer may be sufficient to contact the singulated electronic component to the socket.

The expression “lead backer” may denote a part of the nest. The lead backer or lead backers may support terminals of the electronic component when the terminals may be contacted to DUT sided contacts of a socket. In particular, there may be lead backers on each side where a singulated component has terminals which must be supported for contacting. If the web is fixedly coupled to the chamber lid and not suspended with an elastic suspension, then the web may be lifted off while contacting so that the electronic component may not be clamped by the nest during the contact operation. Moreover, and as an alternative, the nest, including the web, the rear element and one or more lead backers, may be suspended with the elastic suspension. In this case, the electronic component may still be clamped by the nest during contacting since the web may do not lift off.

According to an exemplary embodiment of the contact device, the nest may protrude from the chamber lid in the direction towards the open front side of the chamber.

The expression “protrudes from the chamber lid” may denote that something juts out from the surrounding surface of the chamber lid. In particular, the nest may jut out from the surrounding surface of the chamber lid. In particular, the at least one lead backer and/or the rear element may protrude from the chamber lid. After moving back the nest by using the plunger rod the electronic components may be exchanged. If the rear element and the at least one lead backer protrude from the chamber lid it may be easier to exchange the electronic component.

According to an exemplary embodiment of the contact device, the chamber comprises an outlet for applying low pressure to the chamber, the low pressure being in particular at least as low so that electrical discharges during a high voltage test of the singulated electronic component may be avoided.

The expression “low pressure” may denote an air pressure being lower than the ambient air pressure.

The expression “discharge during a high voltage test” may denote an abnormal electrical phenomenon also called “flashover” (as through the air to the ground from a high potential source). In particular, an abnormal and sudden electrical discharge may occur between two conducting portions which may be the terminals of the singulated electronic component. The electrical discharge may depend on the air density according to a general law of physics that in a vacuum there are no flashovers possible. By applying lower pressure to the chamber the possibility of flashovers may be reduced.

According to an exemplary embodiment of the contact device, the chamber comprises an inlet for applying high pressure to the chamber for performing a high-pressure test of the singulated electronic component.

The expression “high pressure to the chamber” may denote that the air pressure applied to the chamber may be higher than the ambient air pressure. In particular, the closing force goes beyond the sum of the contact force and the high-pressure force so that there is a force left which actually makes an airtight junction of the chamber lid with the chamber on its open front side. In particular, the chamber may comprise the inlet and the outlet so that depending on the required test environment there may low pressure or high pressure be applied to the chamber, respectively.

According to an exemplary embodiment of the contact device, the chamber comprises an inlet for applying high pressure to the chamber, the high pressure being in particular at least as high so that an electrical discharge during a high voltage test of the singulated electronic component may be avoided.

The expression “discharge during a high voltage test” may denote an abnormal electrical phenomenon also called “flashover” (as through the air to the ground from a high potential source). In particular, an abnormal and sudden electrical discharge may occur between two conducting portions which may be the terminals of the singulated electronic component. The electrical discharge may depend on the pressure according to the Paschen's law. By applying higher pressure to the chamber the possibility of flashovers may be reduced.

According to an exemplary embodiment of the contact device, the nest comprises a rear element and a web which are adapted to clamp the singulated electronic component.

The expression “rear element and a web” may denote two mechanical parts acting together so that the singulated electronic component may be clamped. The web may be formed as a ledge clamping the singulated electronic component in the middle so that there may be free space to access the singulated electronic component at two sides peripherally. In particular, the terminals of the singulated electronic component may be clamped between the lead backer or lead backers and the DUT sided contacts of the socket during testing.

According to an exemplary embodiment of the method the plunger unit comprises at least one plunger rod. The method further comprises exerting a closing force with the plunger rod and moving the chamber lid in a direction to the open front side of the chamber, wherein the closing force may exceed a contact force for contacting to the singulated electronic component.

According to an exemplary embodiment of the method the nest comprises a supporting piece being suspended with an elastic suspension on the chamber lid. The method further comprises exerting a force by the elastic suspension on the supporting piece, which force may be sufficient to enable contacting of the singulated electronic component to the socket.

According to an exemplary embodiment of the method the nest may protrude from the chamber lid in the direction towards the open front side of the chamber.

According to an exemplary embodiment the method further comprises applying a low pressure to the chamber via an outlet, the low pressure may at least be as low so that a flashover during a high voltage test of the singulated electronic component is avoided.

According to an exemplary embodiment the method further comprises applying a high pressure to the chamber via an inlet and performing a high-pressure test of the singulated electronic component.

According to an exemplary embodiment the method further comprises clamping the singulated electronic component with a rear element and a web of the nest.

The terms, expressions and the explanations made according to the contact device may also apply to the method of using the test device.

It should be noted that the term “comprising” does not exclude other elements or steps and the “a” or “an” does not exclude a plurality. Also elements described in association with different embodiments may be combined.

It should also be noted that reference signs in the claims shall not be construed as limiting the scope of the claims.

### BRIEF DESCRIPTION OF THE DRAWING

FIG. 1 shows a schematic view of known automated test equipment

FIG. 2 shows a perspective view of a contact device

FIG. 3 shows a cross-sectional view of the contact device

FIG. 4 shows the contact device with a contacted electronic component 101

FIG. 5a shows a cross-sectional view of a further contact device

FIG. 5b shows the further contact device with a contacted electronic component

FIG. 6 shows the contact device with an adapter board

### DETAILED DESCRIPTION OF THE DRAWING

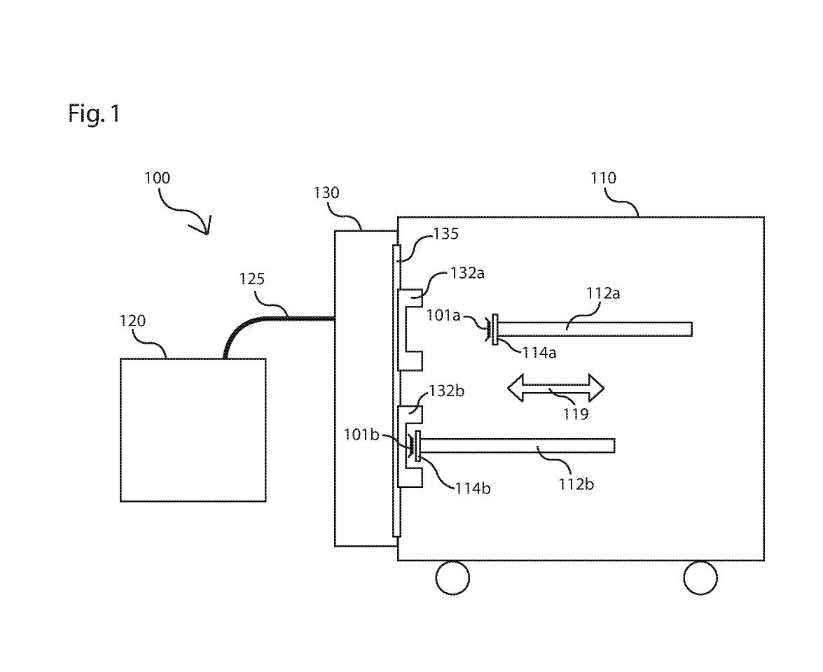

FIG. 1 shows a schematic view of automated test equipment 100 as already known. Automated test equipment 100 comprises at least a handler 110 for handling and sorting electronic components 101a, 101b and a tester 120 for testing the electronic components 101, 101b. A test head 130 may be docked to the handler 110 and may be coupled to the tester 120 by a cable 125 so that an electric contact to the tester 120 may be enabled. Between the test head 130 and the handler 110 a DUT board 135 may be arranged on which a plurality of sockets 132a, 132b may be mounted. The handler 110 may provide for each of the sockets 132a, 132b a plunger 112a, 112b comprising a nest 114a, 114b. Each nest 114a, 114b may carry one electronic component 101a, 101b, respectively, and by a forward and backward movement 119 of the plungers 112a, 112b the electronic components 101a, 101b may be contacted to the sockets 132a, 132b or moved away from the sockets 132a, 132b, respectively. The arrangement of a plunger 112a, 112b and a socket 132a, 132b may be called a contact device 200. As can be seen in FIG. 1 the electronic component 101b may be contacted to the socket 132b by a forward movement of the plunger 112b so that an electric conduct may be established between the electronic component 101b and the tester 120 via the socket 132b, the DUT board 135, and the cable 125. The backward movement of the plunger 112a as can be seen in FIG. 1 illustrates that the respective electronic component 101a may not be contacted and may be sorted after a test carried out by the tester 120.

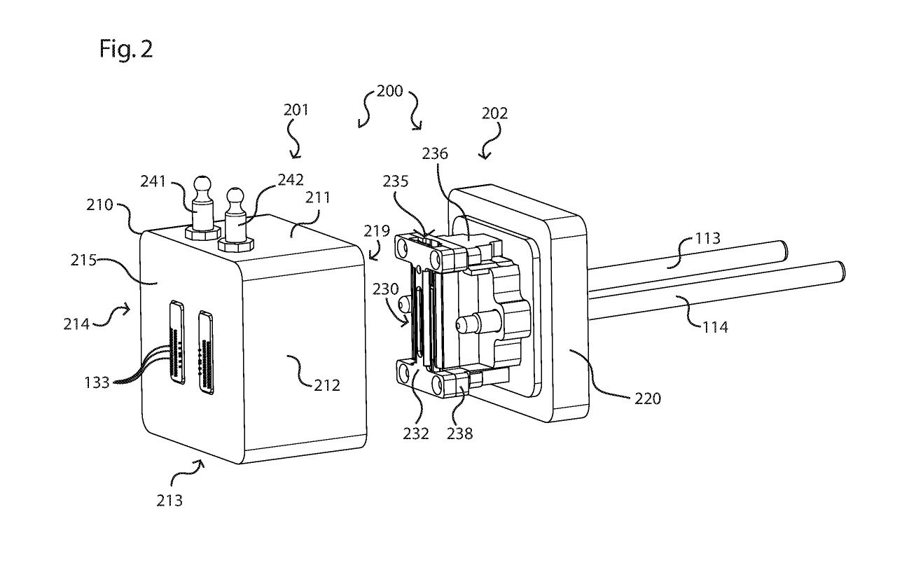

FIG. 2 shows a perspective view of a contact device 200 comprising a plunger unit 202 and a socket unit 201. The plunger unit 202 comprises a first plunger rod 113 and a second plunger rod 114. The first plunger rod 113 and the second plunger rod 114 may allow for a forward and backward movement 119 (see FIG. 1) of the nest 230. The plunger unit 202 may comprise the nest 230 for carrying a singulated electronic component (not shown). The nest 230 may comprise a base 236 on which a rear element 238 of the nest may be fixedly mounted. On the rear element 238 of the nest 230 there may be movably mounted a web 232. The rear element 238 and the web 232 may form a slot 235 through which the electronic component may be fed.

Between the web 232 and the rear element 238 the electronic component may be clamped since the web 232 may be automatically forced towards the rear element 238 by a spring force. In order to clamp an electronic component to the nest 230 the web 232 may first be slightly separated from the rear element 238 against the spring force and then released again. The plunger unit 202 may further comprise a chamber lid 220 on which the base 236 of the nest 230 may be mounted. The nest 230 may extend from the chamber lid 220 into the same direction where a forward movement takes place.

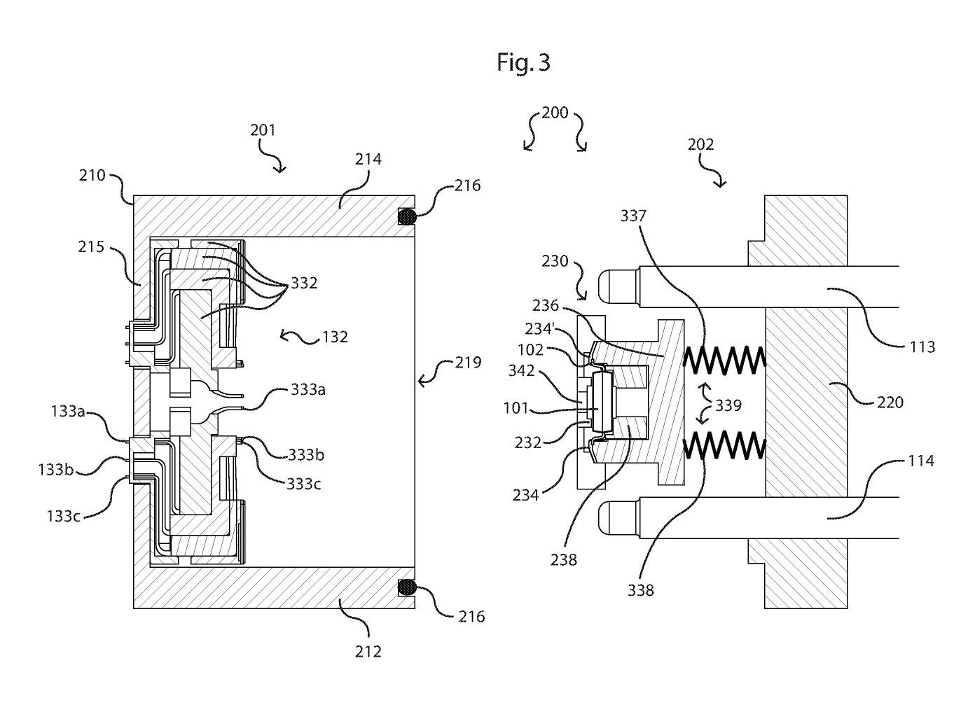

The contact device 200 may further comprise a socket unit 201. The socket unit 201 comprises a chamber 210 which may be concave and may have an open front side 219. The chamber lid 220 may fit to the open front side 219 of the chamber 210. By moving the plunger unit 202 forward the chamber lid 220 may close the chamber 210 so that an inner space may be formed in which the nest 230 may be located. The inner space may be airtight and the nest 230 as well as a socket (see also FIG. 3) may be arranged inside of the chamber 210 closed by the chamber lid 220.

The chamber 210 may be a rectangular cuboid having a first side wall 211 and an opposite third side wall 213, as well as rectangular arranged to them a second side wall 212 and an opposite fourth side wall 214. The chamber may have a back-side wall 215 which may be opposite to an open front side 219. The first, second, third and fourth side walls 211, 212, 213, and 214 may form with the back-side wall 215 a hollow airtight body. The back-side wall 215 may be penetrated by tester sided contacts 133. One of the side walls 211, 212 213, 214 or the back-side wall 215,—here the first side wall 211—may comprise an inlet 241 and an outlet 242. By the inlet 241 and the outlet 242 low pressure and high pressure may be applied to the chamber 210 when being closed by the chamber lid 220.

Summarizing, the contact device 200 may comprise a socket unit 201 and a plunger unit 202. The socket unit 201 may comprise a hollow chamber 210 surrounding the socket 132 (see FIG. 3). The plunger unit 202 may comprise plunger rods 113, 114, and a nest 230 extending from the lid 220 and extending into the chamber 210 if the chamber may be closed by the lid 220.

FIG. 3 shows a cross-sectional view of the contact device 200 in a non-contacted state. The socket unit 201 may comprise the two opposite side walls 212, 214 which may form the hollow body together with the airtight back side wall 215 (and with the other two side walls 211, 213 which, cannot be seen in this cross-sectional view). The chamber 210 may comprise the open front side 219. Inside the chamber 210 a socket 132 may be arranged which provides DUT sided contacts 333a, 333b, 333c which may be adapted to mate with contact terminals 102 of the electronic component 101. The DUT sided contacts 333a, b, c may extend through the socket 132 and through the back-side wall 215 so that an electric conduct path may be established. The socket 132 may be a sandwiched type of construction 332 so that the back-side wall 215 may be penetrated by tester sided contacts 133a, 133b, 133c and the whole chamber construction may be airtight.

An abutting surface of the side walls 211, 212, 213, 214 may comprise a sealing ring 216 which may allow for a complete airtight space inside the chamber 210 when being closed with chamber lid 220 of the plunger unit 202.

The plunger unit 202 may comprise the nest 230, an elastic suspension 339, the two plunger rods 113, 114 and the chamber lid 220. The two plunger rods 113, 114 may extend through the chamber lid 220 in an airtight way. The elastic suspension 339 for the nest 230 may comprise a first spring 337 and a second spring 338. Both springs 337, 338 may be mounted to the chamber lid 220 and to a base 236 of the nest 230, so that the nest 230 and the electronic component 101 held by the nest 230 may be elastically held. The nest 230 may further comprise a rear element 238 which may support the back side of the electronic component 101. The rear element 238 may be fixed to the base 236 so that the rear element 238 may be suspended by the elastic suspension 339, as well. In particular, the base 236 and the rear element 238 may be made from one piece. The electronic component 101 may be clamped between the rear element 238 and a web 232 which is flexibly mounted relative to the rear element 238, so that the electronic component 101 can be removed from the nest 230 when the web 232 is separated from the rear element 238. The web 232 may comprise an opening 342 in a middle area so that the electronic component 101 may be accessible by a DUT sided ground contact 333a of the contact socket 132. Lead backers 234, 234′ may extend from the base 236. The lead backers 234, 234′ may support the terminals 102 of the DUT 101 during the contacting of the DUT 101.

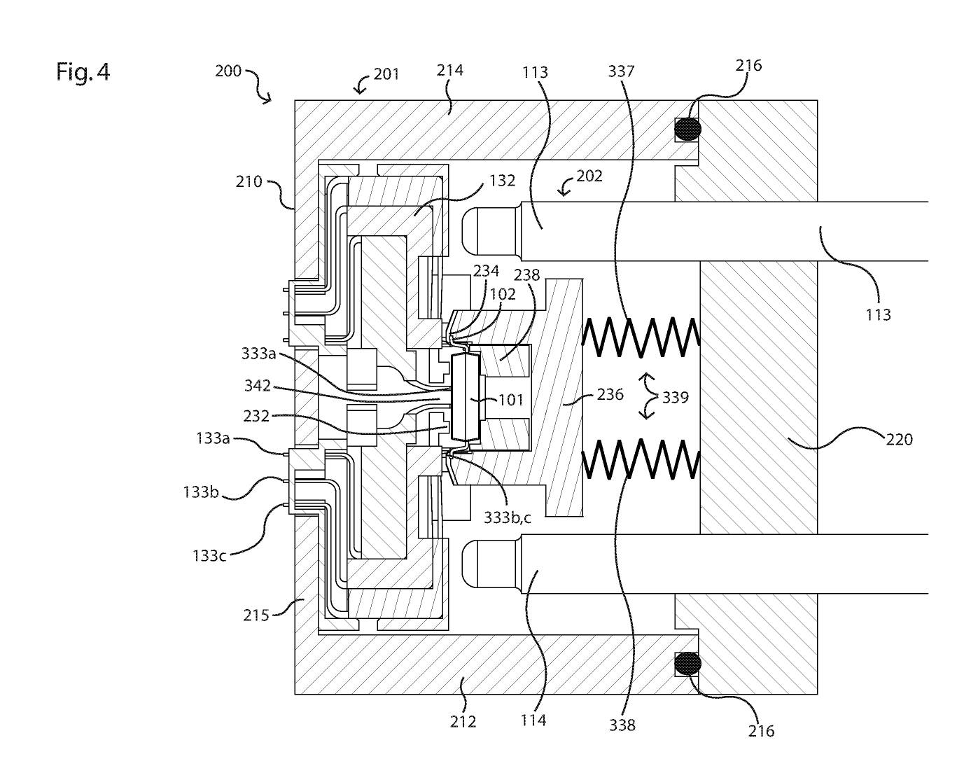

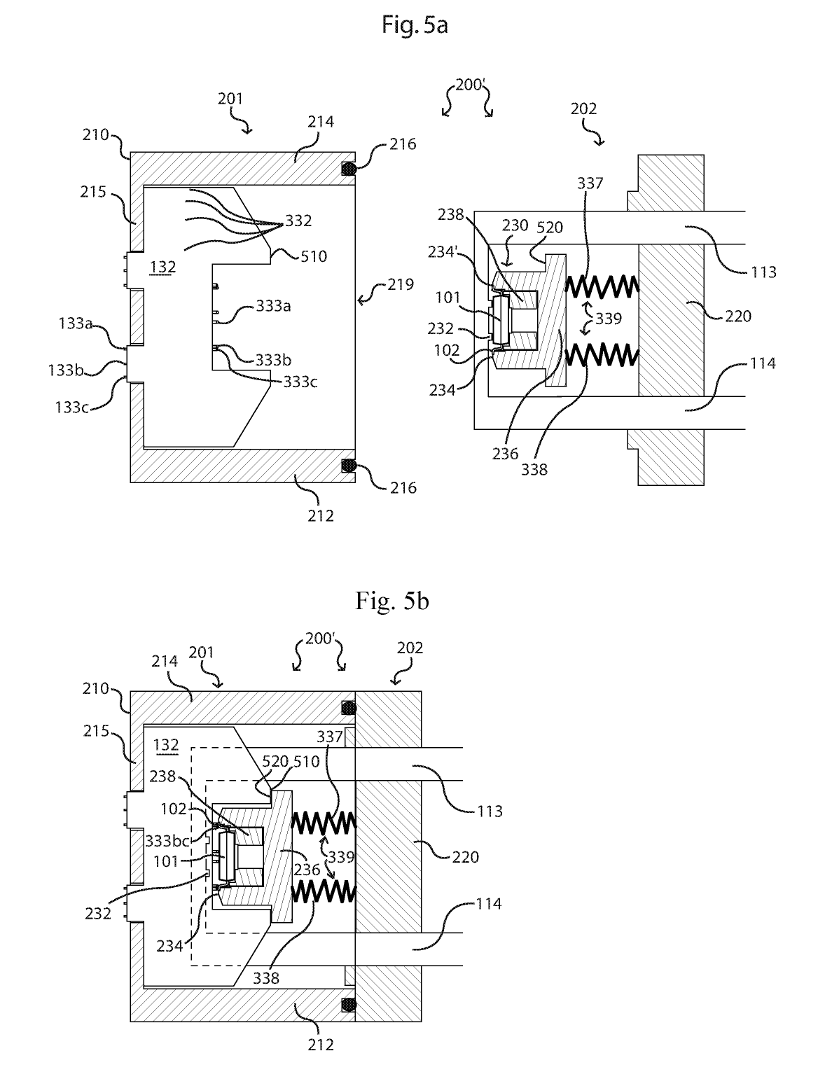

FIG. 4 shows the contact device 200 when an electronic component 101 may be contacted to the socket 132. The side walls 212, 214 (211, 213 see FIG. 2) and the back-side wall 215 of the socket unit 201 and the chamber lid 220 of the plunger unit 202 may form the airtight chamber 210. The force by which the plunger unit 202 may be moved (forwards and) towards the socket unit 201 allows for an appropriate electrical contact of the DUT sided contacts 333a, b, c with the respective terminals 102 of the electronic component 101. The base 236 of the nest 230 may comprise the lead backers 234, 234′ which may support the terminals 102 of the singulated electronic component 101 against an elastic restoring force being exerted by the DUT sided contacts 333a, b, c when the electronic component 101 is contacted to the socket 132. So, the force pressing the plunger unit 202 should be higher than the elastic restoring force of the DUT sided contacts 333a, b, c since the chamber 210 has also to be air-tightly closed. If there is a high pressure applied to the inner space of the chamber for a pressure test of the electronic component 101 by the inlet 241 (see FIG. 2) then the force of the plunger unit 202 should exceed this additional high pressure force. The elastic suspension 339 of the nest 230 may prevent the DUT sided contacts 333a, b, c and the terminals 102 of the electronic component 101 from being damaged since a hard stop may be avoided. Additionally, the elastic suspension 339 may help to overcome fabrication tolerances of the construction which may otherwise cause bad contacting. When the electronic component 101 may be contacted to the DUT sided contacts 333a, b, c then an electric conduct may be established between the DUT and the tester sided contacts 133a, 133b, 133c which may be electrically coupled to the tester 120 (compare FIG. 1). The web 232 may also be suspended with the elastic suspension 339. Therefore, during the contact procedure the DUT 101 may be clamped between the web 232 and the rear element 238. Further, the terminals 102 of the DUT 101 may be supported by the lead backers 234, 234′. A slightly different form of suspension 339 is shown and discussed in FIG. 5a and FIG. 5b.

FIG. 5a and FIG. 5b show an exemplary embodiment of the further contact device 200′ being very similar to the contact device 200 shown in FIG. 3 and FIG. 4. Primarily the suspension 339 of the nest 230 differs, so that only the differences are emphasized. FIG. 5a shows the non-contacted state in which the DUT 101 may be clamped by the web 232 and the rear element 238. The lead backers 234, 234′ may support the terminals 102 of the DUT 101. The lead backers 234, 234′ may extend from the base 236 of the nest 236. The base 236 may comprise the rear element 238 and may comprise an abutting face 520 adapted to abut on an abutting surface 510 of the socket 132. However, the web 232 may be rigidly coupled to the lid 220 and so the suspension 339 may press the rear element 238 against the web 232 so that the DUT 101 may be clamped between the rear element 238 and the web 232.

FIG. 5b shows the contact device 200′ during a contacted state. The abutting face 520 of the base 236 and the abutting surface 510 of the socket 132 may abut on each other. Since the web 232 may be fixed to the chamber lid 220 and does not interact with the socket 132, the web 232 may lift off the DUT 101 which is then not being clamped in the nest 230. However, the back side of the DUT 101 may be supported by the rear element 238 and the terminals 102 may be supported by the lead backers 234, 234′. The terminals 102 being supported by the lead backers 234, 234′ may be contacted to the DUT sided contacts 333a, b, c of the socket 132. The slightly different contact device 200′ may comprise less movable suspended parts since the web 232 is fixedly coupled with the chamber lid 220.

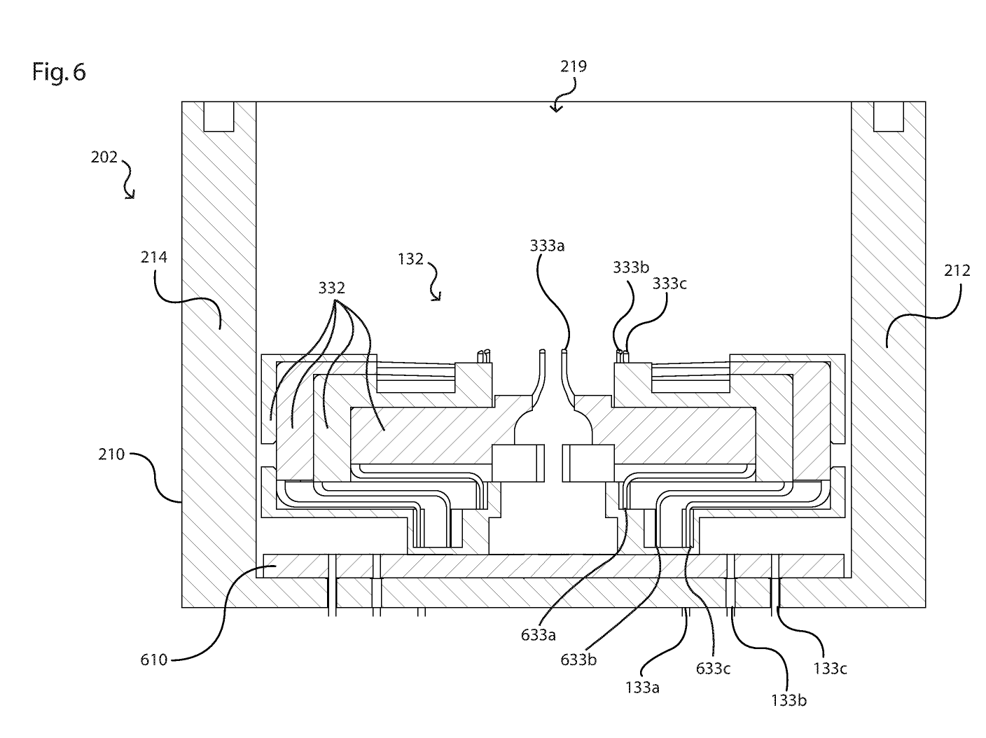

FIG. 6 shows a cross-sectional view of the socket unit 201 using an adapter board 610. A regular socket 132 may be used since the air tightness of the chamber 210 may be realized by the adapter board 610. The tester sided contacts 133a, b, c of the adapter board 610 may be electrically coupled to the tester sided contacts 633a, b, c of the socket 132. An electric conduct may be established from the DUT sided contacts 333a, b, c to the tester 120, via the adapter board 610. The use of the adapter board 610 may allow for using a regular socket 132 which sandwiched type of construction 332 then does not have to be airtight.

1. A contact device for testing a singulated electronic component comprises:
a plunger unit comprising a chamber lid and a nest which is adapted to carry the singulated electronic component, and
a socket unit comprising a socket and a chamber having an open front side and surrounding the socket, wherein
the chamber is adapted in that closing of the chamber at its open front side by the chamber lid comprises automatically contacting the singulated electronic component to the socket.

2. The contact device according to claim 1, wherein
the plunger unit further comprises at least one plunger rod which exerts a closing force that moves the chamber lid in a direction to the open front side of the chamber and which moving force exceeds a contact force for contacting to the singulated electronic component.

3. The contact device according to claim 1, wherein
the nest comprises a supporting piece being suspended with an elastic suspension on the chamber lid so that a force exerted by the elastic suspension on the supporting piece is sufficient to contact the singulated electronic component to the socket.

4. The contact device according to claim 1, wherein
the nest protrudes from the chamber lid in the direction towards the open front side of the chamber.

5. The contact device according to claim 1, wherein
the chamber comprises an outlet for applying low pressure to the chamber, the low pressure being in particular at least as low so that an electrical discharge during a high voltage test of the singulated electronic component is avoided.

6. The contact device according to claim 1, wherein
the chamber comprises an inlet for applying a high pressure to the chamber for performing a high-pressure test of the singulated electronic component.

7. The contact device according to claim 1, wherein
the nest comprises a rear element and a web which are adapted to clamp the singulated electronic component.

8. A method of testing a singulated electronic component using a contact device comprises:
providing a plunger unit comprising a chamber lid and a nest which is adapted to carry the singulated electronic component, and
providing a socket unit comprising a socket and a chamber having an open front side and surrounding the socket, wherein
closing of the chamber at its open front side by the chamber lid comprises automatically contacting the singulated electronic component to the socket.

9. The method according to claim 8, wherein
the plunger unit comprises at least one plunger rod, wherein the method further comprises
exerting a closing force with the plunger rod, and
moving the chamber lid in a direction to the open front side of the chamber, wherein the closing force exceeds a contact force for contacting the singulated electronic component to the socket.

10. The method according to claim 8, wherein
the nest comprises a supporting piece being suspended with an elastic suspension on the chamber lid, wherein the method further comprises
exerting a force by the elastic suspension on the supporting piece, which force is sufficient to enable contacting of the singulated electronic component to the socket.

11. The method according to claim 8, wherein
the nest protrudes from the chamber lid in the direction towards the open front side of the chamber.

12. The method according to claim 8, further comprising
applying a low pressure to the chamber via an outlet, the low pressure being at least as low so that a flashover during a high voltage test of the singulated electronic component is avoided.

13. The method according to claim 8, further comprising
applying a high pressure to the chamber via an inlet and
performing a high-pressure test of the singulated electronic component.

14. The method according to claim 8, further comprising
clamping the singulated electronic component with a rear element and a web of the nest.
